(19) United States
(12) Patent Application Publication
(10) Pub. No.: US 2007/0076495 A1
(43) Pub. Date: Apr. 5, 2007

(54) Wafer-level burn-in test method, wafer-level burn-in test apparatus and semiconductor memory device

(75) Inventors: Noriaki Mochida, Tokyo (JP); Chiaki Dono, Tokyo (JP); Tomohiko Sato, Tokyo (JP)

Correspondence Address: MCDERMOTT WILL & EMERY LLP, 600 13TH STREET, N.W., WASHINGTON, DC, 20005-3096, US

(73) Assignee: ELPIDA MEMORY, INC.

(21) Appl. No.: 11/633,570

(22) Filed: Dec. 5, 2006

(30) Foreign Application Priority Data
Jul. 12, 2005 (JP) 2005-353523

(51) Int. Cl. G11C 29/00

(52) U.S. Cl. 365/201

(57) ABSTRACT

A wafer-level burn-in test for a write operation to memory cells is disclosed. The memory cells are associated with a column switch transistor having a gate. In accordance with the method, a voltage level supplied for the gate is changed in correspondence with a level written into the memory cells. When a stress voltage is written into the memory cells, the gate of the column switch transistor is applied with a high level voltage, ex. a voltage higher than a normal VDD. When a zero voltage is written into the memory cells, the gate of the column switch transistor is applied with a low level voltage, ex. a zero voltage or a negative voltage.

### BACKGROUND OF THE INVENTION

This invention relates to a method of a wafer-level burn-in test for a semiconductor memory device such as a dynamic random access memory (DRAM) device. The invention also relates to an apparatus usable in the test method and a semiconductor memory device suitable for the test method.

In order to identify known good dies (KGDs), modern chip manufacturing includes a wafer-level burn-in test which is carried out for semiconductor devices exercised at a wafer level. Normally, a wafer-level burn-in test for a semiconductor memory device comprises a high level write operation test and a low level write operation test; the former test applies memory cells with a stress voltage higher than a normal power supply voltage (normal VDD), and the latter test applies the memory cells with a zero voltage or a negative voltage.

U.S. Pat. No. 6,930,938 discloses a semiconductor memory device and a wafer-level burn-in test for the device, the contents of U.S. Pat. No. 6,930,938 being incorporated herein by reference in its entirety. The disclosed test makes a pre-charge voltage higher than a normal power supply voltage and uses it as the stress voltage.

For acceleration of date input/output speed in modern semiconductor memory devices, peripheral circuits such as sense amplifiers and column switch transistors are constituted by thin film transistors, as explained in U.S. Pat. No. 6,930,938, column 5, lines 49 to 65. To prevent the stress voltage from damaging thin film transistors of peripheral circuits, the disclosed semiconductor memory device turns transfer gate transistors off during a burn-in test to separate the peripheral circuits from the burn-in test, as explained in U.S. Pat. No. 6,930,938, column 7, lines 6 to 13.

However, the structure of the disclosed semiconductor memory device does not allow that two pairs of bit lines share a pre-charge/equalizing circuit which consists of two pre-charge transistors and an equalizing transistor. Therefore, the disclosed semiconductor memory device has a problem on downsizing thereof. There is a need for a novel technique which allows that two pairs of bit lines share a pre-charge/equalizing circuit while preventing the stress voltage from damaging thin film transistors of peripheral circuits.

### SUMMARY OF THE INVENTION

One aspect of the present invention provides a method of a wafer-level burn-in test for a write operation to memory cells, which are associated with a column switch transistor having a gate. The method includes a step of changing, in correspondence with a level written into the memory cells, a voltage level supplied for the gate.

Another aspect of the present invention provides an apparatus usable in a wafer-level burn-in test for a write operation to memory cells included in a memory device. The memory device further comprises bit lines, column switch transistors and column select lines. The bit lines are coupled to the memory cells. The column switch transistors are coupled to the bit lines, respectively. The column switch transistors have gates, respectively. The column select lines are coupled to the gates, respectively, so that the column select lines are associated with the bit lines, respectively. The apparatus comprises a stress voltage generator and a predetermined voltage generator. The stress voltage generator is configured to generate a stress voltage which is applied as a high level voltage to at least ones of the bit lines during the write operation test. The predetermined voltage generator is configured to generate a predetermined voltage which is applied to the column select lines associated with the stress voltage applied bit lines during the write operation test, wherein the predetermined voltage is higher than a first voltage level but is lower than a second voltage level; the first voltage level is a voltage level supplied as a high level voltage for the gates of the column switch transistors under a normal operation; the second voltage level is a withstand voltage level of the column switch transistors.

Another aspect of the present invention provides a semiconductor memory device which comprises a test mode control circuit, a column switch transistor, a column select line and a column decoder. The test mode control circuit is configured to produce a test signal indicating that a wafer-level burn-in test is a high level write operation test or a low level write operation test. The column switch transistor has a gate, to which the column select line is coupled. The column decoder is configured to apply the column select line with a high level voltage in response to the test signal indicative of the high level write operation test.

An appreciation of the objectives of the present invention and a more complete understanding of its structure may be had by studying the following description of the preferred embodiment and by referring to the accompanying drawings.

### BRIEF DESCRIPTION OF THE DRAWINGS

FIG. 1 is a view schematically showing a wafer-level burn-in test apparatus according to an embodiment of the present invention;

FIG. 2 is a view showing one of semiconductor chips or dies formed on a semiconductor wafer according to an embodiment of the present invention; and

FIG. 3 is a view showing column switch transistors and related circuits thereof, all of which are included in the semiconductor chip of FIG. 2.

While the invention is susceptible to various modifications and alternative forms, specific embodiments thereof are shown by way of example in the drawings and will herein be described in detail. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

### DESCRIPTION OF PREFERRED EMBODIMENTS

An embodiment of the present invention described below is directed to a wafer-level burn-in test method for a semiconductor memory device, especially, for a write operation to memory cells included in the semiconductor memory device. The present inventors have found that there is a problem on that the conventional test method does not control a voltage applied for gates of column switch transistors during the test so that it is fixed to a zero voltage, for example. The conventional test method, especially its high level write operation test causes a problem on each column switch transistor because its gate is applied with a zero voltage while its source is applied with a stress voltage, ex. 3.2 V. In other words, the stress voltage as such is applied to a gate insulator film of each column switch transistor so that the gate insulator is broken or damaged by the stress voltage. Therefore, in order that two pairs of bit lines share a pre-charge/equalizing circuit while preventing a stress voltage from damaging thin film transistors of peripheral circuits, it is most effective to consider protection of column switch transistors. Hence, the present embodiment aims to protect column switch transistors among elements of peripheral circuits included in the semiconductor memory device under a wafer-level burn-in test.

Based on the above, a wafer-level burn-in test method according to the present embodiment includes a step of changing, in correspondence with a level written into memory cells, a voltage level supplied for a gate of a column switch transistor. More specifically, a test target, i.e. a semiconductor memory device comprises memory cells, bit lines, column switch transistors and column select lines, wherein the bit lines are coupled to the memory cells, the column switch transistors are coupled to the bit lines, respectively, the column switch transistors have gates, respectively, and the column select lines are coupled to the gates, respectively, so that the column select lines are associated with the bit lines, respectively, In accordance with the method of the present embodiment, if ones of the bit lines are applied with the stress voltage, a high level voltage is applied for the column select lines associated with the stress voltage applied bit lines; if ones of the bit lines are grounded or applied with a negative voltage, a low level voltage is applied for the column select lines associated with the grounded or negative voltage applied bit lines. In other words, the high level voltage is supplied to the gates of the column switch transistors when the stress voltage is applied to the sources of the column switch transistors. Therefore, the present embodiment can lower a voltage applied for the gate insulator films of the column switch transistors during the high level write operation test using the stress voltage. For example, the high level voltage of 2.7 V is applied to the gates of the column switch transistors so that, even if the stress voltage is 3.2 V, only 0.5 V is applied to the gate insulator films of the column switch transistors.

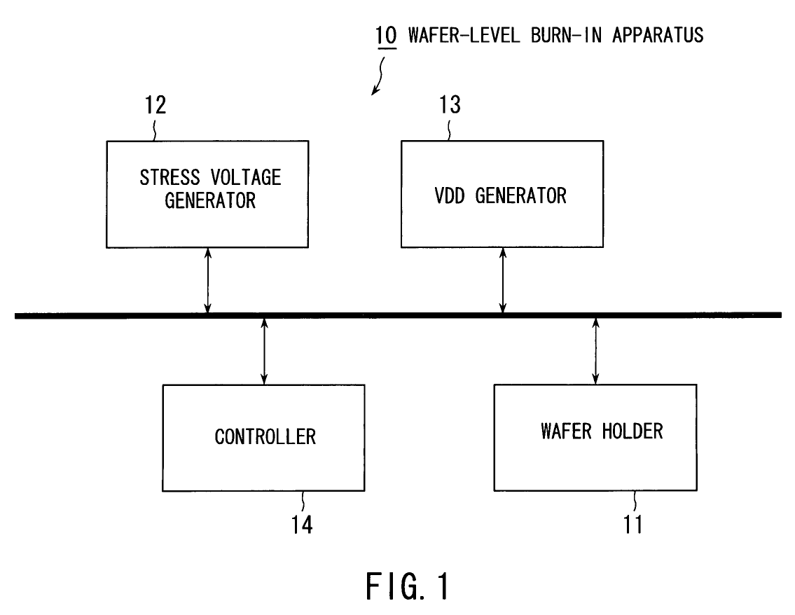

Now, explanation will be made about an apparatus usable in the test method of the present embodiment and a semiconductor memory device suitable for the test method of the present embodiment, with reference to FIGS. 1 to 3. The apparatus is used for testing a semiconductor wafer on which the semiconductor memory devices are formed. Each of the semiconductor memory devices of the present embodiment is a DRAM device. The DRAM device comprises memory cell arrays and peripheral circuits and is provided with a stress voltage pad in addition to an external VDD pad and an external VSS pad, as described in later; the stress voltage pad is to be applied with the stress voltage during the wafer-level burn-in test and is also called a VDL pad.

As shown in FIG. 1, the wafer-level burn-in apparatus 10 comprises a wafer holder 11, a stress voltage generator 12, a VDD generator 13 and a controller 14. The wafer holder 11 is configured to hold a semiconductor wafer. The stress voltage generator 12 is configured to generate a stress voltage that is to be applied to the VDL pad. The VDD generator 13 is configured to generate a test VDD that is to be applied to the external VDD pad. The controller 14 is configured and arranged to control the wafer holder 11, the stress voltage generator 12 and the VDD generator 13. In this embodiment, the controller 14 issues various commands for the semiconductor wafer during the test. In addition, the controller 14 controls the VDD generator 13 so that the test VDD is higher than a normal VDD but is lower than a withstand voltage level of each circuit element included in the peripheral circuits. More specifically, the test VDD of the present embodiment is 2.7 V while the stress voltage is 3.2 V.

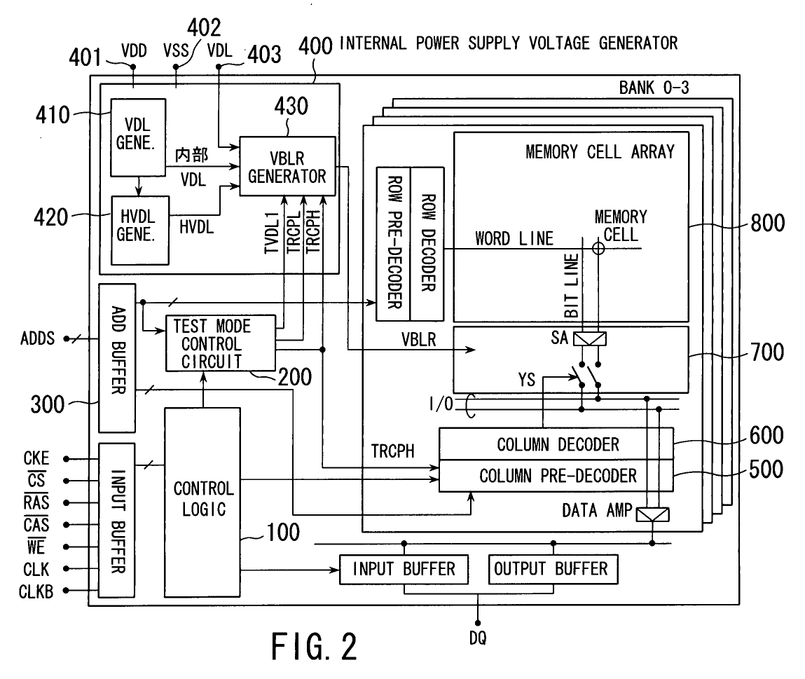

The semiconductor wafer according to the present embodiment contains a plurality of semiconductor chips each of which has a structure illustrated in FIG. 2. Each semiconductor chip, i.e. a DRAM device, comprises a control logic circuit 100, a test mode control circuit 200, an address buffer 300, an internal power supply voltage generator 400, a set of column pre-decoders 500, a set of column decoders 600, a set of sense-amplifier regions 700 and a set of memory cell arrays 800. The column pre-decoders 500, the column decoders 600, row pre-decoders, row decoders and circuit elements formed on the sense-amplifier regions 700 are collectively referred to as peripheral circuits. For simplification of explanation, only one of banks is described hereinafter.

The control logic circuit 100 is configured to receive and interpret a set of command signals including /RAS, /CAS and /WE signals and to control internal behavior of the semiconductor chip in response to a command indicated by the command signals. In detail, when receiving an active command, a read command or a write command upon a normal operation of the semiconductor chip, the control logic circuit 100 controls the row pre-decoder or the column pre-decoder so that the row pre-decoder or the column pre-decoder latches row addresses or column addresses. The control logic also controls an input buffer or an output buffer coupled to data signal (DQ) lines upon the read operation or the write operation. Receiving a predetermined command indicative of entering a test mode, the control logic circuit 100 of the present embodiment 100 notifies it to the test mode control circuit 200.

The test mode control circuit 200 produces a test mode signal TVDL1 and first and second test signals TRCPH and TRCPL in accordance with test details indicated by the address signals. The test mode signal TVDL1 is a signal asserted when a wafer-level burn-in test starts; the test mode signal TVDL1 is delivered to the internal power supply voltage generator 400. The first test signal TRCPH is a signal asserted when the high level write operation test is carried out; the first test signal TRCPH is delivered to the internal power supply voltage generator 400 and the column pre-decoder 500. The second test signal TRCPL is a signal asserted when the low level write operation test is carried out; the second test signal TRCPL is delivered to the internal power supply voltage generator 400.

The internal power supply voltage generator 400 is coupled to the external VDD pad 401, the external VSS pad 402 and the stress voltage pad (VDL pad) 403. To the external VDD pad 401, an external VDD is applied. As described above, the external VDD is the normal VDD during the normal operation but is the test VDD during the test, test VDD being supplied from the apparatus of FIG. 1. To the external VSS pad 402, an external VSS is applied. In this embodiment, the external VSS pad 402 is grounded but may be applied with a negative voltage. To the stress voltage pad (VDL pad) 403, the stress voltage is supplied during the test. When the semiconductor chip is packaged, the external VDD pad 401 and the external VSS pad 402 are connected to an external VDD terminal and an external VSS terminal of the package, such as solder balls. Namely, the external VDD pad 401 and the external VSS pad 402 are used after the semiconductor chip is packaged. On the other hand, the VDL pad of the present embodiment is used only for the test but is not used after the semiconductor chip is packaged.

More in detail, the internal power supply voltage generator 400 comprises a VDL generator 410, an HVDL generator 420 and a VBLR generator 430. The VDL generator 410 is configured to convert the external VDD down into an internal VDL. The internal VDL is a voltage applied for the memory cell arrays. For example, if the external VDD is the normal VDD of 1.8 V, the internal VDL is 1.4 V. The internal VDL is also used as another stress voltage during a post-fabrication burn-in test, i.e. not a wafer-level burn-in test but a normal burn-in or package-level burn-in test. The HVDL generator 420 is configured to generate a HVDL which has a half voltage level of the internal VDL.

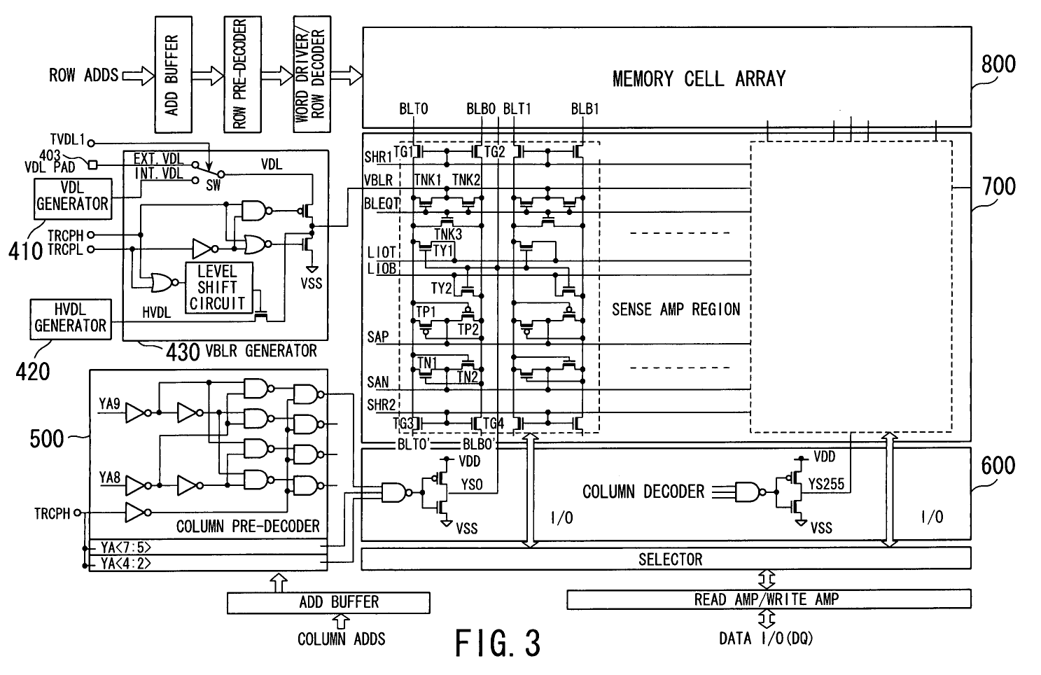

The VBLR generator 430 is a pre-charge voltage generation circuit configured to generate a pre-charge voltage VBLR. As shown in FIG. 3, the VBLR generator 430 comprises a switch SW that is turned on to select the external VDL as a VDL when the test mode signal TVDL1 is asserted; the switch SW is turned off to select the internal VDL as the VDL when the test mode signal TVDL1 is negated. As apparent from FIG. 3, the illustrated VBLR generator 430 outputs the VDL as the pre-charge voltage VBLR when the first test signal TRCPH is asserted while the second test signal TRCPL is negated. In other words, the illustrated VBLR generator 430 outputs the external VDL as the pre-charge voltage VBLR when the following conditions are met: the test mode signal TVDL1 is asserted; the first test signal TRCPH is asserted; and the second test signal TRCPL is negated. In addition, the illustrated VBLR generator 430 outputs the external VSS as the pre-charge voltage VBLR when the first test signal TRCPH is negated while the second test signal TRCPL is asserted. Furthermore, the illustrated VBLR generator 430 outputs the HVDL as the pre-charge voltage VBLR in the normal operation, i.e. when the first and the second test signals TRCPH and TRCPL are negated.

With reference to FIGS. 2 and 3, the column pre-decoder 500 receives column addresses from the address buffer 300 in the normal operation to control the column decoder 600 so that column select lines corresponding the addresses are turned on. Furthermore, the illustrated column pre-decoder 500 further has a function to control, in response to the first test signal TRCPH asserted, the column decoder 600 so that all of the column select lines YS0-YS255 are turned on, i.e. the column select lines YS0-YS255 are applied with a high level voltage, i.e. the external VDD. During the wafer-level burn-in test according to the present embodiment, no column address is inserted into the semiconductor chip so that the column select lines YS0-YS255 are fixed at a low level voltage, i.e. VSS=0V, unless the first test signal TRCPH is asserted.

The illustrated column decoder 600 is configured to apply the column select lines YS0-YS255 with the external VDD or the external VSS in accordance with the control by the column pre-decoder 500, as described above.

On the illustrated sense-amplifier region 700, sense amplifiers SA (only one is shown in FIG. 2), column switch transistors TY1, TY2, pre-charge/equalizing circuits and transfer gate transistors TG1-TG4. Each sense amplifier SA comprises two pMOS transistors TP1, TP2 and two nMOS transistors TN1, TN2, which are arranged and connected in a cross-coupled inverter configuration. Each column switch transistor TY1, TY2 is a switch that, when a corresponding one of the column select lines YS0-YS255 is applied with the external VDD, is turned to connect between a bit line BLT0 (BLT0′) or BLB0 (BLB0′) and a local I/O line LIOT or LIOB. Each pre-charge/equalizing circuit comprises two pre-charge transistors TNK1, TNK2 and an equalizing transistor TNK3. The pre-charge/equalizing circuit is configured to supply the bit lines with the output of the VBLR generator 430, i.e. the pre-charge voltage VBLR when a pre-charge signal BLEQT is high. The transfer gate transistors TG1-TG4 are configured in order that two pairs of bit lines share a sense amplifier and a pre-charge/equalizing circuit. More specifically, the illustrated transfer gate transistors TG1 and TG2 connect or disconnect between a pair of bit lines BLT0, BLB0 and a set of a sense amplifier and a pre-charge/equalizing circuit in accordance with a share signal SHR1. Likewise, the illustrated transfer gate transistors TG3 and TG4 connect or disconnect between another pair of bit lines BLT0′, BLB0′ and the set of the sense amplifier and the pre-charge/equalizing circuit in accordance with another share signal SHR2. During the wafer-level burn-in test of the present embodiment, the share signals SHR1, SHR2 are fixed at the high level voltage, and the pre-charge is also fixed at the high level voltage. Therefore, during the test of the present embodiment, the bit lines BLT0, BLT0′, BLB0, BLB0′ are applied with the output of the VBLR generator 430, i.e. the external VDL or the external VSS.

Now, explanation will be directed to operations of the semiconductor memory device of FIGS. 2, 3 during the wafer-level burn-in test of the present embodiment using the aforementioned apparatus illustrated in FIG. 1. During the test, the test mode control circuit 200 asserts the test mode signal TVDL1 so that the switch SW of the VBLR generator 430 turns on, resulting in that the external VDL supplied through the VDL pad 403 is used as the VDL within the VBLR generator 430. In addition, in order to select the high level write operation test or the low level write operation test, the test mode control circuit 200 asserts one of the first and the second test signals TRCPH, TRCPL, while negating the other.

When the first test signal TRCPH is asserted while the second test signal TRCPL is negated, the VBLR generator 430 outputs the external VDL as the pre-charge voltage VBLR; the external VDL is 3.2 V in this embodiment. Since the pre-charge signal BLEQT is fixed at the high level voltage during the test as mentioned above, the external VDL of 3.2 V is applied to the bit lines BLT0, BLT0′, BLB0, BLB0′ so that the sources of the column switch transistors TY1, TY2 are applied with the external VDL of 3.2 V. On the other hand, in response to the asserted first test signal TRCPH, the column pre-decoder 500 controls the column decoder 600 so that the column select lines YS0-YS255 are applied with the external VDD, i.e. the test VDD of 2.7 V in this embodiment. Therefore, in accordance with the present embodiment, only 0.5 V is applied to the gate insulator films of the column switch transistors TY1, TY2 even in the high level write operation test.

When the first test signal TRCPH is negated while the second test signal TRCPL is asserted, the VBLR generator 430 outputs the external VSS as the pre-charge voltage VBLR; the external VSS is 0 V in this embodiment. Since the pre-charge signal BLEQT is fixed at the high level voltage during the test as mentioned above, the external VSS of 0 V is applied to the bit lines BLT0, BLT0′, BLB0, BLB0′ so that the sources of the column switch transistors TY1, TY2 are applied with the external VSS of 0 V. On the other hand, in response to the negated first test signal TRCPH and no column address input, the column pre-decoder 500 controls the column decoder 600 so that the column select lines YS0-YS255 are applied with the external VSS of 0 V Therefore, 0 V is applied to the gate insulator films of the column switch transistors TY1, TY2 in accordance with the present embodiment.

As described above, the present embodiment lowers a voltage level applied to the gate insulator films of the column switch transistors during the test so that the stress voltage can be prevented from breaking or damaging the column switch transistors TY1, TY2 during the wafer-level burn-in test.

While there has been described what is believed to be the preferred embodiment of the invention, those skilled in the art will recognize that other and further modifications may be made thereto without departing from the sprit of the invention, and it is intended to claim all such embodiments that fall within the true scope of the invention.

What is claimed is:

1. A method of a wafer-level burn-in test for a write operation to memory cells, the memory cells being associated with a column switch transistor having a gate, the method including changing, in correspondence with a level written into the memory cells, a voltage level supplied for the gate.

2. A method of a wafer-lever burn-in test for a memory device including column switch transistors, each of the column switch transistors having a gate and a source, the method including supplying a high level voltage to the gates when a stress voltage is applied to the sources.

3. A method of a wafer-level burn-in test for a write operation to memory cells included in a memory device, the memory device further comprising bit lines, column switch transistors and column select lines, the bit lines being coupled to the memory cells, the column switch transistors being coupled to the bit lines, respectively, the column switch transistors having gates, respectively, the column select lines being coupled to the gates, respectively, so that the column select lines are associated with the bit lines, respectively, the method including:
if ones of the bit lines are applied with a stress voltage, supplying a high level voltage for the column select lines associated with the stress voltage applied bit lines; and
if ones of the bit lines are grounded or applied with a negative voltage, supplying a low level voltage for the column select lines associated with the grounded or negative voltage applied bit lines.

4. The test method according to claim 3, simultaneously testing the memory cells coupled to all of the bit lines, wherein:
when the bit lines are applied with the stress voltage, all of the column select lines are supplied with the high level voltage; and
when the bit lines are grounded or applied with the negative voltage, all of the column select lines are supplied with the low level voltage.

5. The test method according to claim 3, wherein the stress voltage is applied by using a pre-charge voltage related circuit.

6. The test method according to claim 3, wherein the high level voltage is higher than a first voltage level but is lower than a second voltage level, the first voltage level being a voltage level supplied as a high level voltage for the gates of the column switch transistors under a normal operation, the second voltage level being a withstand voltage level of the column switch transistors.

7. An apparatus usable in a wafer-level burn-in test for a write operation to memory cells included in a memory device, the memory device further comprising bit lines, column switch transistors and column select lines, the bit lines being coupled to the memory cells, the column switch transistors being coupled to the bit lines, respectively, the column switch transistors having gates, respectively, the column select lines being coupled to the gates, respectively, so that the column select lines are associated with the bit lines, respectively, the apparatus comprising:
a stress voltage generator configured to generate a stress voltage which is applied as a high level voltage to at least ones of the bit lines during the write operation test; and
a predetermined voltage generator configured to generate a predetermined voltage which is applied to the column select lines associated with the stress voltage applied bit lines during the write operation test, the predetermined voltage being higher than a first voltage level but being lower than a second voltage level, the first voltage level being a voltage level supplied as a high level voltage for the gates of the column switch transistors under a normal operation, the second voltage level being a withstand voltage level of the column switch transistors.

8. An apparatus usable in a wafer-level burn-in test carried out for a semiconductor wafer, the semiconductor wafer being to be a semiconductor memory device comprising memory cell arrays and peripheral circuits, the peripheral circuits comprising a plurality of circuit elements, the semiconductor wafer being provided with a first pad and a second pad, the first pad being to be applied with a stress voltage during the test, the second pad being to be supplied with an external VDD, the external VDD being a power supply voltage of the peripheral circuits, the apparatus comprising:
a stress voltage generator configured to generate the stress voltage to supply the stress voltage for the first pad; and
a VDD generator configured to generate a test voltage to supply the test voltage for the second pad, the test voltage being higher than a normal VDD but being lower than a withstand voltage level of each of the circuit elements.

9. A semiconductor memory device comprising:
a test mode control circuit configured to produce a test signal indicating that a wafer-level burn-in test is a high level write operation test or a low level write operation test;
a column switch transistor having a gate;
a column select line coupled to the gate of the column switch transistor; and
a column decoder configured to apply the column select line with a high level voltage in response to the test signal indicative of the high level write operation test.

10. The semiconductor memory device according to claim 9, further comprising:
a bit line coupled to the column switch transistor;
a pre-charge transistor configured to supply a pre-charge voltage to the bit line;
a stress voltage pad configured to be applied with a stress voltage during the test; and
a pre-charge voltage generation circuit configured to supply the pre-charge transistor with the stress voltage as the pre-charge voltage in response to the test signal indicative of the high level write operation test, so that the stress voltage is applied to the bit line through the pre-charge transistor.

11. The semiconductor memory device according to claim 10, further comprising:
two pairs of bit lines including the bit line;
two pairs of transfer gate transistors coupled to the bit lines, respectively;
a sense amplifier circuit coupled to the two pairs of bit lines through the two pairs of transfer gate transistors and positioned between the two pairs of transfer gate transistors; and
a pair of pre-charge transistors including the pre-charge transistor, the pair of pre-charge transistors being coupled to the two pairs of bit lines through the two pairs of transfer gate transistors and being positioned between the two pairs of transfer gate transistors.

12. The semiconductor memory device according to claim 9, further comprising a column pre-decoder configured to, in response to the test signal indicative of the high level write operation test, control the column decoder so that the high level voltage is applied to the column select line.

13. The semiconductor memory device according to claim 9, wherein:
the test signal comprises a set of first and second test signals;
in order to indicate the high level write operation test, the test mode control circuit asserts the first test signal while negating the second test signal; and
in order to indicate the low level write operation test, the test mode control circuit negates the first test signal while asserting the second test signal.

14. The semiconductor memory device according to claim 9, further comprising a column pre-decoder configured to, in response to the test signal indicative of the high level write operation test, control the column decoder so that the high level voltage is applied to the column select line, wherein:
the test signal comprises a set of first and second test signals;
in order to indicate the high level write operation test, the test mode control circuit asserts the first test signal and negates the second test signal;
in order to indicate the low level write operation test, the test mode control circuit negates the first test signal and asserts the second test signal; and
only the first test signal of the first and the second test signals is delivered to the column pre-decoder.
